(19) United States
(12) Patent Application Publication
(10) Pub. No.: US 2014/0308822 A1
(43) Pub. Date: Oct. 16, 2014

(54) DEPOSITION TECHNIQUE FOR DEPOSITING A COATING ON A DEVICE

(71) Applicant: Anthony O'Hara, Lothian (GB)

(72) Inventor: Anthony O'Hara, Lothian (GB)

(73) Assignee: MEMSSTAR LIMITED, Lothian (GB)

(21) Appl. No.: 14/241,643

(22) PCT Filed: Aug. 31, 2012
(86) PCT No.: PCT/GB2012/052127

§ 371 Date: Jun. 30, 2014

(30) Foreign Application Priority Data
Sep. 1, 2011 (GB) 1115105.7

(51) Int. Cl. B81C 1/00

(52) U.S. Cl. CPC B81C 1/00952; B81C 1/0038; B81C 2201/112
USPC 438/780; 427/58

(57) ABSTRACT

The present invention describes a deposition method suitable for depositing a coating on a device. The method is particularly suited for depositing a self assembled monolayer (SAM) coating on a micro electro-mechanical structures (MEMS). The method employs carrier gases in order to form a deposition vapour in a process chamber within which the device is located wherein the deposition vapour comprises controlled amounts of a vapour precursor material and a vapour reactant material. Employing the described technique avoids the problematic effects of particulate contamination of the device even when the volumetric ratio of the reactant material to the precursor material is significantly higher than those ratios previously employed in the art. The vapour precursor material can be of a type that provides the MEMS with an anti-stiction coating with the associated vapour reactant material comprising water.

The present invention relates to the field of deposition of coatings. In particular, an improved deposition technique for producing thin films or coatings on a device is described which has particular application for the deposition of self assembled monolayer (SAM) coatings on micro electro-mechanical structures (MEMS).

The production processes for MEMS make use of layers or coatings of material which are deposited on a substrate for various purposes. In some instances, the layers are deposited on a substrate and then are subsequently removed, such as when the layer is used as a patterned masking material and then removed after the pattern is transferred to an underlying layer. In other instances, the layers are deposited to perform a predefined function as part of the completed fabricated device. A number of methods for depositing these thin film layers or coatings are known to those skilled in the art, for example: sputter deposition, where a plasma is used to sputter atoms from a target material (commonly a metal), and the sputtered atoms deposit on the substrate; chemical vapour deposition, where activated (e.g. by means of plasma, radiation, or temperature, or a combination thereof) species react either in a vapour phase (with subsequent deposition of the reacted product on the substrate) or react on the substrate surface to produce a reacted product on the substrate; evaporative deposition, where evaporated material condenses on a substrate to form a layer; and spin-on, spray-on, or dip-on deposition, typically from a solvent solution of the coating material, where the solvent is subsequently evaporated to leave the coating material on the substrate.

Given that MEMS generally exhibit large surface-area-to-volume ratios one of the most difficult problems to overcome during their fabrication process is the effects of stiction. Stiction relates to the unintentional adhesion of compliant microstructure surfaces resulting when restoring forces are unable to overcome interfacial forces such as capillary, van der Waals and electrostatic attractions. Release stiction, which is the adhesion of surface MEMS to the underling substrate following a final sacrificial etch, is primarily caused by liquid capillary forces.

Historically engineering solutions have been developed to alleviate the problems of stiction. However, most of these techniques fail to prevent adhesion from occurring during normal operation of the MEMS. For example, surfaces within a MEMS may unintentionally come into contact during use due to acceleration or electrostatic forces. Alternatively, some surfaces may intentionally come into contact in applications where surfaces impact or shear against one another. However, when the adhesive attraction forces exceed the restoring forces the surfaces will permanently adhere to each other so causing device failure. This phenomenon is known in the art as in-use stiction.

In order to reduce the effects of stiction it is therefore necessary to control the topography and/or the chemical composition of the contacting surfaces. One known solution involves the deposition of self assembled monolayer (SAM) coatings upon the MEMS. A number of different chemical compositions have been employed to form SAM coatings depending upon the function they are intended to perform. For example, SAM coatings have been employed in the art so as to provide areas of the MEMS with a hydrophobic, hydrophilic or bioactive functionality. When desired to be employed to provide an anti-stiction coating it is normal practice to provide a precursor material having an inorganic part that bonds well onto silicon and/or silicon dioxide surfaces (e.g. a silane compound) and an organic part that provides a hydrophobic functionality for the device (e.g. a long chain fluorocarbon).

Such precursor materials tend to be in a liquid phase at room temperature (20° C.) and standard atmospheric pressure (760 Torr). As a result early techniques for depositing SAM anti-stiction coatings for MEMS employed liquid or wet deposition techniques. Two examples are provided within the papers by Ashurst, et al, namely “Dichlorodimethylsilane as an anti-stiction monolayer for MEMS: A comparison to the octadecyltrichlosilane self assembled monolayer”, Journal of Microelectromechanical Systems, Vol. 10, No. 1, March (2001) and “Alkene based monolayer films as anti-stiction coatings for polysilicon MEMS”, Proceedings of Solid-state Sensor & Actuator Workshop, Hilton Head 2000, Hilton Head Island, S.C., pp 320-323 (2000). The first of these papers provides a comparison between dichlorodimethylsilane (DDMS) and octadecyltrichlosilane (OTS) for use as anti-stiction monolayers upon MEMS while the second of these papers provides a comparison between 1-octadecene, octadecyltrichlosilane (OTS) and perfluorodecyltrichlorosilane (FDTS).

SAM coatings deposited by liquid or wet deposition techniques have a number of significant drawbacks. In the first instance these techniques involve complicated process control requirements. Water (H₂O) is known to act as a reactant material to promote the deposition reaction but too much water being present acts to promote excessive polymerisation of the precursor material resulting in large clumps of material being formed, commonly referred to as particulate contamination. Furthermore, employing these techniques generates large amounts of contaminated effluents, often result in insufficient stiction prevention and involve high production costs.

Alternative techniques that can eliminate some of the known problems with liquid-based processes are the so called vapour phase processing techniques. In general vapour phase processing allows greater control of the levels of material present in a reaction chamber. They can also be exploited to ensure precise and consistent vapour delivery. By way of example: Ashurst et al in “Improved vapour-phase deposition technique for anti-stiction monolayers”, Proceedings of the SPIE: Photonics West 2004, Vol 5342, San Jose, Calif. January 24-29, pp 204-211 (2004) teaches of a vapour phase deposition method and apparatus for depositing SAMs of dichlorodimethylsilane (DDMS), tetrahydrooctyltrichlorosilane (FOTS) and perfluorodecyltrichlorosilane (FDTS); Zhuang et al in “Vapor-phase self-assembled monolayers for anti-stiction applications in MEMS”, Journal of Microelectromechanical Systems, Vol 16, No 6, pp 1451-1460, December (2007) teach of SAMs grown in vapour phase from tetrahydrooctyltrichlorosilane (FOTS), tetrahydrooctylTriethoxysilane (FOTES), tetrahydrooctylMethyldichlorosilane (FOMDS) perfluorodecyltrichlorosilane (FDTS) and octadecyltrichlosilane (OTS); Mayer et al in “Chemical vapor deposition of fluoroalkysilane monolayer films for adhesion control in microelectromechanical systems”, J. Vac. Sci. Tecnol. B 18(5). (September/October 2000) teach of a vapour deposition technique for applying a tetrahydrooctyltrichlorosilane (FOTS) coating to a MEMS; and US patent publication numbers 2005/0051086 teaches of apparatus for depositing a layer of hexamethyldisalizane (HDMS) on a MEMS.

Many of the above described precursor materials however have very low vapour pressures, meaning that at a standard room temperature very little vapour is generated. A number of approaches have therefore been developed to facilitate vapour phase processing employing these precursor materials.

US patent publication number 2002/0164879 describes the employment of a precursor materials comprising a vapour phase alkylsilane-containing molecules. The precursor material is employed to form a coating over a substrate surface of a MEMS. The alkylsilane-containing molecules are introduced into a reaction chamber containing the substrate by bubbling an anhydrous, inert gas through a liquid source of the alkylsilane containing molecules, to transport the molecules in the vapour phase into the reaction chamber. The formation of the coating is carried out on a substrate surface at a temperature ranging between about 15° C. and 100° C., at a pressure in the reaction chamber which is said to be below atmospheric pressure, and yet sufficiently high for a suitable amount of alkylsilane-containing molecules to be present for expeditious formation of the coating. The inventors state that the alkylsilane-containing molecules utilised for forming the coating are typically highly reactive with water, and accordingly it is desirable that any water residue associated with the assembly is removed from within the reaction chamber prior to the introduction of the precursor material.

US patent publication numbers 2005/0051086 and 2007/019694 describe vapour phase arrangements where the substrate comprises a batch of MEMS placed in an oven or a furnace along with a compound of the appropriate precursor material. The oven or furnace is then heated to a temperature sufficient to vaporise the precursor material e.g. 300° C. to 500° C. resulting in the deposition of an anti-stiction coating upon the MEMS. In a similar manner to that described above, pre-deposition procedures are employed so as to eliminate water vapour from the substrate and oven in order to eliminate unwanted polymerisation. As a result of these operating parameters the described deposition techniques take a relatively long time to complete, even at these high operating temperatures e.g. typically of the order of 30 to 40 minutes.

US patent publication number 2005/0109277 teaches of an alternative delivery method where the precursor material and associated reactant material are processed within expansion vapour reservoirs before being transported to the process chamber within which the MEMS devices are located. The inventors teach of employing dichlorodimethylsilane (DDMS), tetrahydrooctyltrichlorosilane (FOTS) and perfluorodecyltrichlorosilane (FDTS) precursor material and a water vapour reactant material. The process chamber is operated at a pressure ranging from 100 mTorr to 10 Torr and a temperature ranging from 30° C. to 60° C. The amount of water is again required to be carefully controlled so as to avoid the problem of excessive polymerisation of the precursor material resulting in particulate contamination of the MEMS being coated. However, unlike the previously described prior art water is controllably transferred to the process chamber. The volumetric ratio of the precursor material to a reactant material is described as ranging from 1:6 to 6:1. Under such conditions the reaction time period ranges from 5 minutes to 30 minutes for FOTS or DDMS precursor materials, a fact confirmed by the teaches of Mayer et al. Mayer et al state however that employing this technique to deposit a FDTS precursor material takes considerably longer.

It is therefore an object of an embodiment of the present invention to provide a deposition technique for producing thin films or coatings on a device, for example a MEMS, that obviates, or at least mitigates, the disadvantages of the methods described in the prior art.

### SUMMARY OF THE INVENTION

According to a first aspect of the present invention there is provided a deposition method suitable for depositing a coating on a device, the method comprising:
providing a process chamber within which the coating is to be deposited;
providing a vapour of one or more precursor materials to the process chamber;
providing a vapour of one or more reactant materials to the process chamber wherein a deposition vapour is formed within the process chamber, the deposition vapour comprising a volumetric ratio of the reactant material to the precursor material greater than 6:1.

The above method has the advantage that increased rates of deposition of the coating are achieved without excessive polymerisation of the precursor material resulting in particulate contamination of the device being coated as would be expected for such a volumetric ratio between the reactant material and the precursor material. This increased rate of deposition is further assisted by the fact that the operating pressure within the process chamber can also be set to be significantly higher than those employed within the prior art systems. A further advantage of the presently described technique is that there is no need to heat the process chamber in order to achieve the required precursor vapour pressures for deposition to take place.

The volumetric ratio of the reactant material to the precursor material may be greater than or equal to 10:1

The volumetric ratio of the reactant material to the precursor material may be greater than or equal to 50:1

The volumetric ratio of the reactant material to the precursor material may be greater than or equal to 100:1

Preferably an operating pressure within the process chamber is greater than 10 Torr. The operating pressure may be greater than or equal to 40 Torr. The operating pressure may be greater than or equal to 100 Torr.

Most preferably the vapour of the one or more precursor materials is provided to the process chamber by transporting the vapour of the one or more precursor materials from outside of the process chamber. The vapour of the one or more precursor materials may be transported to the process chamber by passing a carrier gas through one or more bubbler chambers.

Most preferably the vapour of the one or more reactant materials is provided to the process chamber by transporting the vapour of one or more reactant materials from outside of the process chamber. The vapour of the one or more reactant materials may be transported to the process chamber by passing a carrier gas through one or more bubbler chambers.

Employing carrier gases and bubbler chambers provides a means for transporting the desired volumes of the precursor material and the reactant material vapour to the process chamber.

Preferably the one or more precursor materials comprise perfluorodecyltrichlorosilane (FDTS). Alternatively, or in addition, the one or more precursor materials may comprise a precursor material selected from group of precursor materials comprising dichlorodimethylsilane (DDMS), octadecyltrichlosilane (OTS), 1-octadecene, tetrahydrooctyltrichlorosilane (FOTS), tetrahydrooctylTriethoxysilane (FOTES), tetrahydrooctylMethyldichlorosilane (FOMDS) and hexamethyldisalizane (HDMS).

Alternatively the one or more precursor materials comprise a precursor material selected from group of precursor materials comprising precursor materials having a hydrophilic organic part or a bioactive organic part.

Most preferably the one or more reactant materials comprises water (H₂O).

The carrier gas is preferably an inert gas such as nitrogen or a nitrogen-based gas. Alternatively the carrier gas may comprise helium.

The method may further comprise cleaning and/or ionising the micro electro-mechanical structures (MEMS). Preferably the cleaning and/or ionising of the micro electro-mechanical structures (MEMS) takes place within the process chamber prior to the provision of the vapour of one or more precursor materials and the provision of the vapour of one or more reactant materials to the process chamber.

Optionally the method further comprises heating one or more vapour supply lines. Heating the vapour supply lines ensures that there is no condensation of the precursor vapour therein.

Most preferably the coating comprises a self assembled monolayer (SAM) coating.

Most preferably the device comprises a micro electro-mechanical structures (MEMS).

Alternatively the device may comprise a semiconductor structure

In a further alternative the device may comprise a mobile device e.g. a mobile phone, a smartphone, a personal digital assistant, a tablet computer or a laptop computer.

In a yet further alternative the device may comprise a textile or cloth.

According to a second aspect of the present invention there is provided a method of depositing a coating on a micro electro-mechanical structures (MEMS), the method comprising:
providing a process chamber within which the coating is to be deposited;
providing a vapour of one or more precursor materials to the process chamber;
providing a vapour of one or more reactant materials to the process chamber wherein a deposition vapour is formed within the process chamber, the deposition vapour comprising a volumetric ratio of the reactant material to the precursor material greater than 6:1.

Preferably the coating comprises a self assembled monolayer (SAM).

Embodiments of the second aspect of the invention may include one or more features of the first aspect of the invention or its embodiments, or vice versa.

According to a third aspect of the present invention there is provided a method of depositing a coating on a micro electro-mechanical structures (MEMS), the method comprising:
providing a process chamber within which the coating is to be deposited;
transporting a vapour of one or more precursor materials to the process chamber;
transporting a vapour of one or more reactant materials to the process chamber wherein a deposition vapour is formed within the process chamber, the deposition vapour comprising a volumetric ratio of the reactant material to the precursor material is greater than 6:1.

Preferably the coating comprises a self assembled monolayer (SAM).

Most preferably the vapour of the one or more precursor materials is transported to the process chamber by passing a carrier gas through one or more bubbler chambers.

Most preferably the vapour of the one or more reactant materials is transported to the process chamber by passing a carrier gas through one or more bubbler chambers.

Embodiments of the third aspect of the invention may include one or more features of the first or second aspects of the invention or its embodiments, or vice versa.

According to a fourth aspect of the present invention there is provided a deposition method suitable for depositing a self assembled monolayer (SAM) coating on a micro electro-mechanical structures (MEMS), the method comprising:
providing a process chamber within which the coating is to be deposited;
providing a vapour of one or more precursor materials to the process chamber; and
providing a vapour of one or more reactant materials to the process chamber; wherein a volumetric ratio of the reactant material to the precursor material is greater than 6:1.

Embodiments of the fourth aspect of the invention may include one or more features of the first, second or third aspects of the invention or its embodiments, or vice versa.

### BRIEF DESCRIPTION OF THE DRAWINGS

There will now be described, by way of example only, various embodiments of the invention with reference to the drawings, of which:

FIG. 1 illustrates in schematic form a vapour deposition system suitable for depositing a self assembled monolayer (SAM) coating on a micro electro-mechanical structures (MEMS); and

FIG. 2 provides a flow chart diagram illustrating a method of depositing a self assembled monolayer (SAM) coating on a micro electro-mechanical structures (MEMS).

### DETAILED DESCRIPTION OF PREFERRED EMBODIMENTS

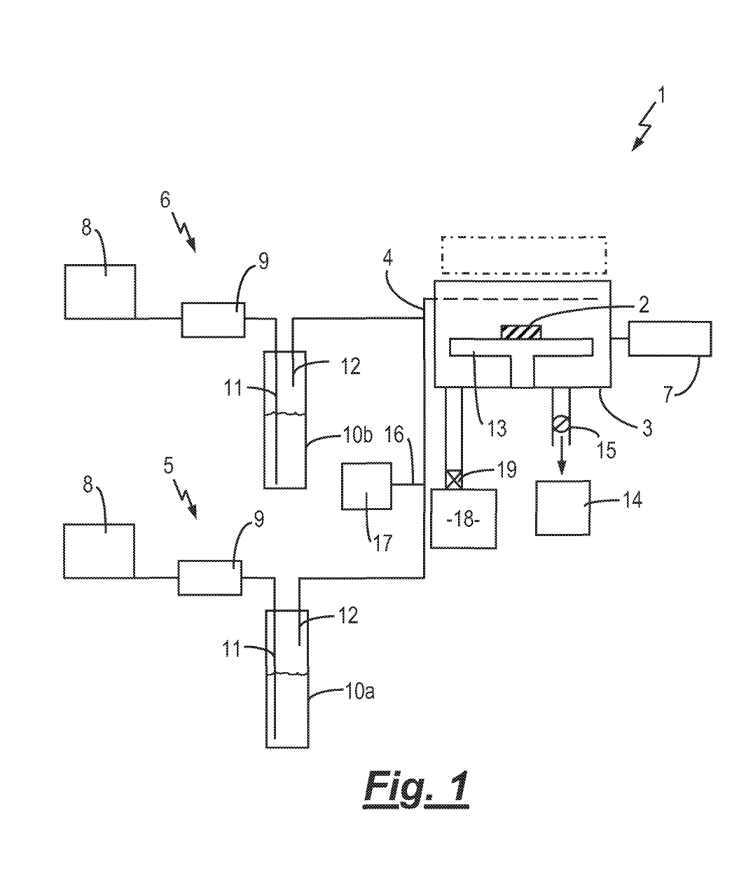

With reference to FIG. 1, there is presented a vapour deposition system 1 suitable for depositing a self assembled monolayer (SAM) coating on a micro electro-mechanical structures (MEMS) 2.

The vapour deposition system 1 can be seen to comprise a process chamber 3 attached to which, via a vapour supply line 4, are first 5 and second 6 vapour sources. A pressure gauge 7 monitors the pressure within the process chamber 3. Each vapour source 5 and 6 comprises a carrier gas source 8 which provides a carrier gas, the flow rate of which is determined by a mass flow controller (MFC) 9, to an associated a bubbler chamber 10. In the presently described embodiment the first bubbler chamber 10a comprises a precursor material while the second 10b comprises the associated reactant material to assist the deposition reaction within the process chamber 3.

Each bubbler chamber 10 comprises a carrier gas inlet 11 and a carrier gas outlet 12. The carrier gas thus travels through the associated bubbler chamber 10 to the process chamber 3, via the vapour supply line 4, and so provides a means for transporting the desired volumes of precursor and reactant material vapour to the process chamber 3. The carrier gas is preferably an inert gas such as nitrogen or a nitrogen-based gas. Alternatively the carrier gas may comprise helium. The vapour supply lines 4 may be heated so as to ensure that there is no condensation of the precursor vapour.

A pedestal 13 is located within the process chamber 3 in order to provide a means for locating the MEMS 2 for the deposition process. The pedestal may also be heated if required.

The pumping rate of a vacuum pump 14 connected to the process chamber 3 via an adaptive pressure controller (APC) 15 in the pumping line and/or the MFCs 9 can be employed to provide a means for accurately controlling the operating pressure within the process chamber 3.

Also connected to the supply line 4 (or, alternatively, directly to the process chamber 3) is a chamber purge line 16 connected to a purge vapour source 17. Similarly to the carrier gas lines, the flow rate of the purge vapour is determined by a mass flow controller (MFC). The purge vapour is preferably an inert gas such as nitrogen or a nitrogen-based gas. Alternatively the purge vapour may comprise helium.

A downstream RF plasma source 18 is also connected to the process chamber 3 via an plasma control valve 19. The RF plasma source is preferably an oxygen (O₂) plasma source.

In other alternative embodiments a plurality of bubbler chambers 10 may be employed such that the process chamber 3 is provided with two or more vapour precursor materials and/or two or more corresponding vapour reactant materials.

Method for Depositing a Self Assembled Monolayer (SAM)

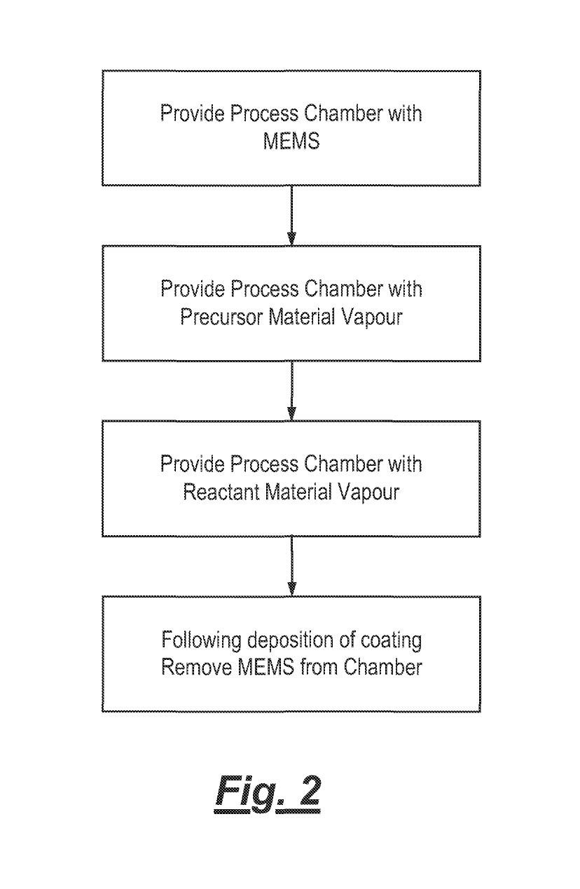

A method for depositing a self assembled monolayer (SAM) coating on a micro electro-mechanical structures (MEMS) 2 that employs the vapour deposition system 1 of FIG. 1 will now be described with reference to FIG. 2.

The precursor material that is considered in the art to provide the best anti-stiction performance combined with temperature performance is perfluorodecyltrichlorosilane (FDTS). However, such trichlorosilanes have been found to be the most susceptible to particulate contamination. Other materials that are easier to deposit in terms of taking less time and having fewer particulate contamination issues have therefore often been employed as an alternative precursor materials. Therefore, to best demonstrate the advantages of the presently described technique the following described embodiment employs perfluorodecyltrichlorosilane (FDTS) as the precursor material while the reactant material is water (H₂O).

In the first instance the MEMS 2 is located within the process chamber 3. The plasma source 18 is then introduced to the process chamber 3 so as to clean the surface of the MEMS 2 prior to the SAM coating deposition process being initiated. The chamber pressure during the plasma treatment is typically around 0.5 Torr with the RF power in the range of 100 to 300 watts. It is preferable for the MEMS 2 to be treated by the plasma while located within the process chamber 3, prior to the deposition of the SAM coating and with no additional processing steps occurring in between. Alternatively the MEMS 2 can be treated with a remote plasma source prior to being located within the process chamber 3.

The SAM deposition process then commences with a nitrogen carrier gas being provided to the first 10a and second 10b bubbler chambers so as to provide a predetermined amount of FDTS vapour and water vapour, respectively, to the process chamber 3. The FDTS vapour and water vapour thus form a single deposition vapour within the process chamber 3. The amount of FDTS vapour and water vapour provided to the process chamber depends on carrier the carrier gas flow rate, the temperature and pressure of the bubbler chambers 10a and 10b and the process chamber 3.

In the absence of any heating of the FDTS precursor material i.e. at typical room temperature 20° C. the precursor vapour can be transferred to the process chamber by the carrier gas in sufficient volumes to allow for the deposition process to take place. The technique also allows the FDTS precursor vapour to be continually flowed into the process chamber where the reaction conditions are precisely controlled.

By way of example a flow rate of 30 standard cubic centimetres per minute (sccm) of the nitrogen carrier gas is set to flow thorough the first bubbler 10a so as to provide 1 sccm of FDTS precursor material to the process chamber. At the same time a 100 sccm flow rate of the nitrogen carrier gas is set to flow thorough the second bubbler 10b so as to provide a 50 sccm of water vapour to the process chamber. The vacuum pump 14 and the adaptive pressure controller (APC) are employed to maintain an operating pressure of 40 T for the deposition vapour within the process chamber 3. The pressure chamber 3 was operated at room temperature ˜20° C. however the vapour supply lines were heated to ensure no condensation of the FDTS precursor material therein.

As will be recognised by the skilled reader the volumetric ratio of the FDTS precursor material to the water reactant material within the formed deposition vapour is 1:50. This is significantly greater than the teachings of the prior art which consistently teach that in such conditions excessive polymerisation of the FDTS precursor material would take place resulting in large clumps of FDTS material forming thus causing particle contamination. Somewhat surprisingly with the above described deposition flow technique and precise chamber control a very fast FDST anti-stiction SAM coating is achieved with no unwanted vapour phase polymerisation. In the presently described conditions the FDTS SAM coating was deposited in under five minutes which is considerably faster than those results previously reported.

Once the deposition of the SAM is complete the MEMS 2 can be removed from the process chamber 3. The process chamber 3 may be purged, via the chamber purge line 16, so as to remove the deposition vapour prior to the MEMS 2 device being removed.

The inventors have been able to reproduce the fabrication of a FDTS anti-stiction coating by varying the volumetric ratio of the FDTS precursor material to the water reactant material within the deposition vapour. Indeed the suggested upper limit for the volumetric ratio of the reactant material to the precursor material of 6:1 is not limiting at all within the presently described technique i.e. the volumetric ratio of the water reactant material to the FDTS precursor material may be greater than 6:1 within the deposition vapour and indeed increased as high as 100:1.

As result of employing a carrier gas and bubbler chambers 10a and 10b to provide the process chamber 3 with the precursor material the pressure chamber 3 does not need to be lowered to the normal operating pressures reported in the prior art, typically below 10 Torr, in order to obtain the required vapour pressures of the precursor material. The inventors have been able to reliably fabricate a FDTS anti-stiction coating at operating pressures of 100 Torr and above. These higher pressures are one factor which assist in reducing the time taken for the deposition process to be completed.

The fast deposit rates of the FDTS SAM coating, in the absence of particle contamination, is believed to be a result of a number of factors. The low flow rate of the precursor vapour is believed to reduce the chance of a gas phase reaction and hence polymerisation taking place, therefore no particulate contamination occurs. This low flow rate also allows the deposition process to be performed at a high pressure which increases the surface reaction rate and thus increases the SAM coating deposition rate.

The inventors have observed similar improved rates of deposition of anti-stiction coatings on MEMS by employing dichlorodimethylsilane (DDMS), octadecyltrichlosilane (OTS), 1-octadecene, tetrahydrooctyltrichlorosilane (FOTS), tetrahydrooctylTriethoxysilane (FOTES), tetrahydrooctylMethyldichlorosilane (FOMDS) and hexamethyldisalizane (HDMS) as the precursor material within the above described flow rate deposition technique.

The inventors have found that for some precursor materials there is a slight improvement to the homogeneous nature of the SAM coating when the pedestal 13 is heated. The maximum temperature employed within these processes was 40° C. as no significant difference to the homogeneous nature of the SAM coating was observed above this temperature.

The above techniques are not limited to the deposition of anti-stiction coatings. For example it is envisaged that the techniques may equally well be suited to the application of precursor materials having an hydrophilic organic part or a bioactive organic part where previously it was similarly believed that no water, or carefully controlled levels of water, was required in order to reduce the effects of particle contamination of the MEMS upon which the coating is to be deposited.

In addition the above techniques are not limited to devices that comprise MEMS structures. The inventors have also applied these techniques so as to apply coatings to semiconductor structures. The application of coatings to a mobile device (e.g. a mobile phone, a smartphone, a personal digital assistant, a tablet computer or a laptop computer), a textile or cloth is also possible by applying the above described techniques.

The present invention exhibits a number of advantages over the methods for depositing coatings or thin layers on MEMS previously described in the art. In the first instance significantly greater levels of water can be introduced to the process chamber than previously described. This is somewhat surprising given the efforts of the prior art teachings to either remove water from the described techniques or to carefully control the levels of water so as to avoid particle contamination of the MEMS upon which the coating is to be deposited. In addition, the operating pressure within the described technique can be significantly higher than those employed within the prior art systems. The combination of both of these operating parameters is such that the deposition times of the precursor materials are significantly lower than those previously reported within the prior art.

A further advantage of the presently described technique is that there is no need to heat the process chamber in order to achieve the required precursor vapour pressures. This is of obvious benefit because it makes the process, and associated set up, less complex and so makes the overall process more cost effective.

The present invention describes a deposition method suitable for depositing a coating on a device. The method is particularly suited for depositing a self assembled monolayer (SAM) coating on a micro electro-mechanical structures (MEMS). The method employs carrier gases in order to form a deposition vapour in a process chamber within which the device is located wherein the deposition vapour comprises controlled amounts of a vapour precursor material and a vapour reactant material. Employing the described technique avoids the problematic effects of particulate contamination of the device even when the volumetric ratio of the reactant material to the precursor material is significantly higher than those ratios previously employed in the art. The vapour precursor material can be of a type that provides the MEMS with an anti-stiction coating with the associated vapour reactant material comprising water.

The foregoing description of the invention has been presented for the purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims.

1. A deposition method suitable for depositing a coating on a device structures the method comprising:
providing a process chamber within which the coating is to be deposited;
providing a vapour of one or more precursor materials to the process chamber; and
providing a vapour of one or more reactant materials to the process chamber;
wherein a deposition vapour is formed within the process chamber, the deposition vapour comprising a volumetric ratio of the reactant material to the precursor material is greater than 10:1.

2. (canceled)

3. The deposition method according to claim 1, wherein the volumetric ratio of the reactant material to the precursor material is greater than or equal to 50:1.

4. The deposition method according to claim 1, wherein the volumetric ratio of the reactant material to the precursor material is greater than or equal to 100:1.

5. The deposition method according to claim 1, wherein an operating pressure within the process chamber is greater than 10 Torr.

6. The deposition method according to claim 1, wherein operating pressure is greater than or equal to 40 Torr.

7. The deposition method according to claim 1, wherein the operating pressure is greater than or equal to 100 Torr.

8. The deposition method according to claim 1, wherein the vapour of the one or more precursor materials is provided to the process chamber by transporting the vapour of the one or more precursor materials from outside of the process chamber.

9. The deposition method according to claim 8, wherein the vapour of the one or more precursor materials is transported to the process chamber by passing a carrier gas through one or more bubbler chambers.

10. The deposition method according to claim 1, wherein the vapour of the one or more reactant materials is provided to the process chamber by transporting the vapour of one or more reactant materials from outside of the process chamber.

11. The deposition method according to claim 10, wherein the vapour of the one or more reactant materials is transported to the process chamber by passing a carrier gas through one or more bubbler chambers.

12. The deposition method according to claim 1, wherein the one or more precursor materials comprise perfluorodecyltrichlorosilane (FDTS).

13. The deposition method according to claim 1, wherein the one or more precursor materials comprise a precursor material selected from the group of precursor materials comprising dichlorodimethylsilane (DDMS), octadecyltrichlosilane (OTS), 1-octadecene, tetrahydrooctyltrichlorosilane (FOTS), tetrahydrooctylTriethoxysilane (FOTES), tetrahydrooctylMethyldichlorosilane (FOMDS) and hexamethyldisalizane (HDMS).

14. The deposition method according to claim 1, wherein the one or more precursor materials comprise a precursor material having a hydrophilic organic part or a bioactive organic part.

15. The deposition method according to claim 1, wherein the one or more reactant materials comprises water (H₂O).

16. The deposition method according to claim 9, wherein the carrier gas is an inert gas such as nitrogen or a nitrogen-based gas.

17. The deposition method according to claim 9, wherein the carrier gas comprises helium.

18. The deposition method according to claim 1, further comprising cleaning and/or ionising the micro electro-mechanical structures (MEMS).

19. The deposition method according to claim 18, wherein the cleaning and/or ionising of the micro electro-mechanical structures (MEMS) takes place within the process chamber prior to the provision of the vapour of one or more precursor materials and the provision of the vapour of one or more reactant materials to the process chamber.

20. The deposition method according to claim 1, further comprising heating one or more vapour supply lines.

21. The deposition method according to claim 1, wherein the coating comprises a self assembled monolayer (SAM) coating.

22. The deposition method according to claim wherein the device comprises a micro electro-mechanical structures (MEMS).

23. The deposition method according to claim wherein the device comprises a semiconductor structure

24. The deposition method according to claim 1, wherein the device comprises a mobile device.

25. The deposition method according to claim 1, wherein the device comprises a textile or cloth.
